(19) United States
(12) Patent Application Publication
(10) Pub. No.: US 2016/0105168 A1
(43) Pub. Date: Apr. 14, 2016

(54) CHIP AND CHIP CONTROL METHOD

(71) Applicant: Samsung Electronics Co., Ltd., Suwon-si (KR)

(72) Inventor: Jong Han KIM, Suwon-si (KR)

(73) Assignee: SAMSUNG ELECTRONICS CO., LTD., Suwon-si (KR)

(21) Appl. No.: 14/658,857

(22) Filed: Mar. 16, 2015

(30) Foreign Application Priority Data
Oct. 14, 2014 (KR) 10-2014-0138377

(51) Int. Cl. H03K 17/06; G11C 8/12

(52) U.S. Cl. CPC H03K 17/06; G11C 8/12

(57) ABSTRACT

Provided is a chip in which operation state information on a main logic unit operating in response to an enable signal is acquired, and determining whether a toggling condition of the main logic unit is satisfied based on the operation state information.

### CROSS-REFERENCE TO RELATED APPLICATION(S)

This application claims the benefit under 35 USC 119(a) of Korean Patent Application No. 10-2014-0138377, filed on Oct. 14, 2014, in the Korean Intellectual Property Office, the entire disclosure of which is incorporated herein by reference for all purposes.

### BACKGROUND

1. Field

The following description relates to a chip and chip control method, and more particularly, to technology for preventing degradation in chip performance.

2. Description of Related Art

As a usage frequency or a usage time of an element in a chip increases, a performance of the element is gradually degraded or power consumption of the element may increase. Meanwhile, logic and cell included in the chip is not renewed to prolong a life of the chip. Additionally, performance of the chip has a relationship with a performance of a terminal device or a system including the chip. Thus, maintaining the performance of the chip is also related to maintaining the performance of the terminal device or the system.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a chip including main logic units, and a controller configured to acquire operation state information on a main logic unit operating in response to an enable signal among the main logic units, determine whether a toggling condition of the main logic unit is satisfied based on the operation state information, and generate a control signal for toggling of the main logic unit based on a result of the determining.

The chip may further include a toggling unit configured to toggle the main logic unit operating in response to the enable signal, based on the control signal.

The operation state information may include one of error information, operation time information, and temperature information on the main logic unit operating in response to the enable signal.

The controller may include an internal timer configured to acquire an operation time of the main logic unit operating in response to the enable signal.

The controller may include a control register configured to store a table in which temperature and bit data is mapped.

The controller may be configured to monitor a performance of the main logic unit operating in response to the enable signal.

The toggling condition may be at least one of a first condition indicating whether an accumulated operation time of the main logic unit operating in response to the enable signal is greater than or equal to a threshold time, a second condition indicating whether a temperature of the main logic unit is greater than or equal to a threshold temperature, and a third condition indicating whether, during a process of applying the enable signal to the main logic unit, a number of errors occurring in a bitstream generated by the main logic unit is greater than or equal to a threshold.

In another general aspect, there is also provided a chip including memory units, one logic unit configured to access the plurality of memory units, and a controller configured to acquire operation state information on a memory unit accessed by the logic unit among the memory units, determine whether a toggling condition of the memory unit is satisfied based on the operation state information, and generate a control signal for toggling of the memory unit based on a result of the determining.

The chip may further include a toggling unit configured to toggle the memory accessed by the logic unit based on the control signal.

The operation state information may include at least one of temperature information and operation time information on the memory unit accessed by the logic unit.

The toggling condition may be at least one of a first condition indicating whether an accumulated operation time of the memory unit accessed by the logic unit is greater than or equal to a threshold time, and a second condition indicating whether a temperature of the memory unit is greater than or equal to a threshold temperature.

The controller may include an internal timer configured to acquire an operation time of the memory unit accessed by the logic unit.

The controller may include a control register configured to store a table in which temperature and bit data is mapped.

In still another general aspect, there is also provided a chip control method including acquiring operation state information on a main logic operating in response to an enable signal among main logics, determining whether a toggling condition of the main logic is satisfied based on the operation state information, and generating a control signal for toggling the main logic based on a result of the determining.

In still another general aspect, the controller includes a combinational logic unit configured to determine a toggling of the main logic unit operating in response to the enable signal based on the operation state information on the main logic unit operating in response to the enable signal, and wherein each of the main logic units is equivalent.

In another general aspect, the controller comprises a switching control unit configured to transmit a control signal to the toggling unit.

In still another aspect, the controller further includes a selection control register configured to select data stored in the table of the control register.

Other features and aspects will be apparent from the following detailed description, the drawings, and the claims.

### BRIEF DESCRIPTION OF THE DRAWINGS

FIG. 1 is a diagram illustrating an example of a chip.

FIG. 2 is a diagram illustrating an example of a digital design logic of a chip.

FIG. 3 is a diagram illustrating another example of a digital design logic of a chip.

FIG. 4 is a flowchart illustrating the determination of a main logic unit described with reference to FIG. 1 and the determination of a main logic block described with reference to FIG. 2.

FIG. 5 is a flowchart illustrating an example of a chip control method.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations described is an example; however, the sequence of and/or operations is not limited to that set forth herein and may be changed as is known in the art, with the exception of steps and/or operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

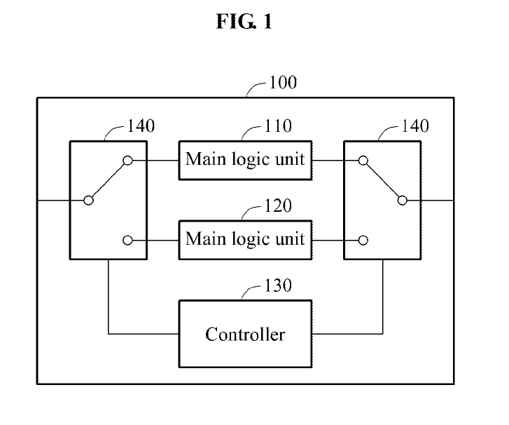

FIG. 1 is a diagram illustrating an example of a chip.

Referring to FIG. 1, the chip 100 includes a plurality of main logic units, for example, main logic units 110 and 120, a controller 130, and a toggling unit 140. Although FIG. 1 illustrates the main logic units 110 and 120, the controller 130, and the toggling units 140 included in the chip 100, the main logic units 110 and 120, the controller 130, and the toggling units 140 may be embodied as independent hardware.

The main logic unit 110 is equal to the main logic unit 120. In the chip 100, the main logic units 110 and 120 perform an identical operation. The chip 100 includes a plurality of equalized logics. The main logic unit 110 or the main logic unit 120 may be the most frequently used logic in the chip 100. Alternatively, the main logic unit 110 or the main logic unit 120 may be the highest power consuming logic in the chip 100.

A logic to be dualized is determined based on a post-layout simulation result. For example, when a post-simulation is applied to an initial digital design, power consumption or an application frequency for logics included in the initial digital design is verified. A logic corresponding to the highest power consumption or application frequency is determined as a main logic unit. As a dualization result of the main logic units, the chip 100 includes main logic units, for example, the main logic units 110 and 120.

The controller 130 acquires state information on the main logic unit 110 operating in response to an enable signal among the plurality of main logic units. The main logic unit 110 is connected to another logic, for example, an external circuit of the chip 100, by the toggling unit 140.

Operation state information includes at least one of error information, temperature information, and operation time information on the main logic unit 110 operating in response to the enable signal. The controller 130 acquires the error information, the temperature information, and the operation time information on the main logic unit 110.

The controller 130 includes an internal timer configured to acquire the operation time information on the main logic unit 110. A clock operates, and the main logic unit 110 operates when the enable signal is applied to the main logic unit 110. The controller 130 calculates an operation time of the main logic unit 110 in response to an application of the enable signal to the main logic unit 110. The operation time of the main logic unit 110 is accumulated, and the controller 130 verifies whether the accumulated operation time of the main logic unit 110 is greater than or equal to a threshold operation time.

When the accumulated operation time of the main logic unit 110 is greater than or equal to the threshold operation time, the controller 130 determines that a toggling condition of the main logic unit 110 is satisfied. The controller 130 generates a control signal for toggling, and transfer the control signal to the toggling unit 140. The toggling unit 140 toggles the main logic unit 110 based on the control signal such that the main logic unit 120 is connected to another logic. The main logic unit 120 operates in response to an application of the enable signal from the controller 130 to the main logic unit 120.

In an example, in response to an occurrence of toggling, the controller 130 initializes the accumulated operation time of the main logic unit 110. Also, in response to an occurrence of toggling to the main logic unit 120, the controller 130 acquires operation time information on the main logic unit 120. The controller 130 verifies whether an accumulative operation time of the main logic unit 120 is greater than or equal to the threshold operation time. When the accumulated operation time of the main logic unit 120 is verified to be greater than or equal to the threshold operation time, the controller 130 generates a control signal to perform toggling to the main logic unit 110. Alternatively, the controller 130 generates a control signal to perform toggling to another main logic unit.

In an example, the controller 130 acquires temperature information on the main logic unit 110. A temperature of the main logic unit 110 is measured by a temperature sensor (not shown). In this example, the temperature sensor is disposed internally or externally to the chip 100. In an example, when the main logic unit 110 operates in response to an application of the enable signal to the main logic unit 110, the temperature sensor measures the temperature of the main logic unit 110. The temperature sensor measures the temperature of the main logic unit 110 based on the enable signal applied to the main logic unit 110. Alternatively, the temperature sensor measures the temperature of the main logic unit 110 when an operation of the main logic unit 110 is terminated. The measured temperature is transmitted to the controller 130. The controller 130 acquires the temperature information of the main logic unit 110.

The controller 130 includes a control register configured to store a table in which temperature and bit data is mapped. For example, the control register stores a table including information indicating that 25° C. is mapped to 0000, 26° C. is mapped to 0001, and 27° C. is mapped to 0010. The control register performs read and write functions. Since the control register performs read and write functions, the mapping of temperature and bit data is changed based on an environment in which the chip 100 is used.

The controller 130 refers to the table stored in the control register, and verifies whether the acquired temperature information on the main logic unit 110 is greater than or equal to the threshold temperature. When the temperature of the main logic unit 110 is greater than or equal to the threshold temperature, the toggling condition of the main logic unit 110 is satisfied. For example, a threshold temperature for the toggling of the main logic unit 110 may be assumed as 30° C. In this example, the controller 130 verifies the temperature of the main logic unit 110 using the temperature sensor. When the measured temperature of the main logic unit 110 is 32° C., the controller 130 determines that the toggling condition of the main logic unit 110 is satisfied.

The controller 130 generates the control signal to toggle to the main logic unit 120, and the toggling unit 140 toggles the main logic unit 110 based on the control signal. In response to the toggling, the main logic unit 120 is connected to the other logic connected to the main logic unit 110 before the toggling. When the toggling is performed and when the main logic unit 120 operates in response to the enable signal, the controller 130 acquires the temperature information on the main logic unit 120. The controller 130 verifies whether the temperature of the main logic unit 120 is greater than or equal to the threshold temperature. When the temperature of the main logic unit 120 is greater than or equal to the threshold temperature, the controller 130 generates the control signal to toggle to the main logic unit 110. Alternatively, the controller 130 generates the control signal to toggle to the other main logic unit.

The toggling unit 140 toggles to the main logic unit 110 based on the control signal. In response to the toggling, the main logic unit 110 is connected to the other logic connected to the main logic unit 120 before the toggling.

In an example, the controller 130 may combine the operation time information and the temperature information on the main logic unit 110, and determine whether the toggling condition of the main logic unit 110 is satisfied. For example, the controller 130 determines that the toggling condition of the main logic unit 110 is satisfied when the accumulated operation time of the main logic unit 110 is greater than or equal to the threshold operation time and when the temperature of the main logic unit 110 operating in response to the application of the enable signal is greater than or equal to the threshold temperature.

In an example, the controller 130 monitors performance of the main logic unit 110. When the performance is less than or equal to a threshold level, the controller 130 determines that the toggling condition of the main logic unit 110 is satisfied. For example, the controller 130 monitors an error occurring in a process of operating the main logic unit 110. In this example, the main logic unit 110 operates while the enable signal is being applied to the main logic unit 110. In response to the operating, the main logic unit 110 may generate a bitstream. The controller 130 counts a number of errors occurring in the bitstream. When the number of errors occurring in the bitstream is greater than or equal to a threshold, the controller 130 determines that the toggling condition of the main logic unit 110 is satisfied.

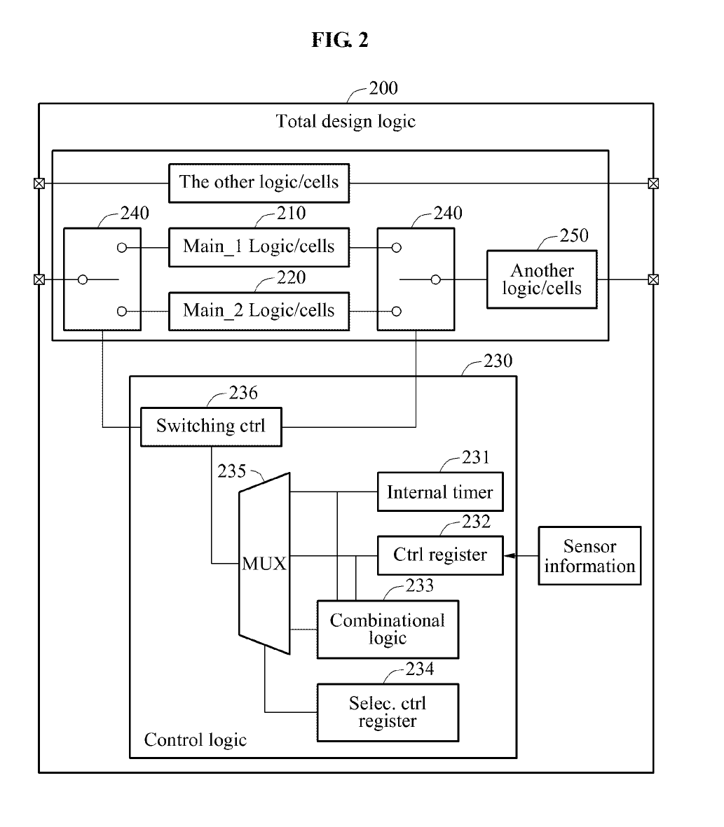

FIG. 2 is a diagram illustrating an example of a total design logic of a chip. Hereinafter, the total design logic 200 may also be referred to as a digital design logic 200. Referring to FIG. 2, the digital design logic 200 includes a plurality of main logic blocks including, for example, a main 1 logic/cells 210, a main 2 logic/cells 220, a control logic block 230, and a switch 240. Hereinafter, the main 1 logic/cells 210 may also be referred to as a main logic block 210, and the main 2 logic/cells 220 may also be referred to as a main logic block 220.

The main logic block 210 may be equivalent to the main logic block 220.

According to an example, a post-layout simulation is applied to an initial digital design logic, and a logic block to be dualized is determined based on a result of the post-layout simulation. In FIG. 2, the logic block to be dualized is the main logic block 210. The digital design logic 200 additionally includes the main logic block 220, the control logic block 230, and the switch 240 when compared to the initial digital design.

The control logic block 230 acquires operation state information on the main logic blocks 210 and 220. To acquire the operation state information, the control logic block 230 includes an internal timer 231, a control register 232, a combinational logic 233, a selection control register 234, a multiplexer (MUX) 235, and a switching control logic 236. When a first signal based on the temperature information, a second signal based on the operation time information, a third signal based on the error information, a fourth signal based on the combinational information by the combinational logic 233 are transferred to the MUX 235, specific signal is selected among the first signal, the second signal, the third signal, and the fourth signal based on a selection signal of the selection control register 234. The selection control register 234 may transfer the selection signal to MUX which is used to select the specific signal. MUX 235 may transfer the specific signal to the switching control logic 236. The switching control logic 236 may generate the control signal for toggling, based on the specific signal. Although FIG. 2 illustrates the internal timer 231, the control register 232, the combinational logic 233, the selection control register 234, the MUX 235 and the switching control logic 236 as being included in the control logic block 230, some of these components may be embodied as independent hardware.

As an example, a switch is switched to the main logic block 210 and thus, the main logic block 210 is connected to another logic/cells 250. Hereinafter, the other logic/cells 250 may also be referred to as the other logic 250. In response to an application of an enable signal, the main logic block 210 transfers data to the other logic 250.

The control logic block 230 determines whether a toggling condition of the main logic block 210 is satisfied based on the operation state information on the main logic block 210.

The internal timer 231 acquires operation time information on the main logic block 210. When an accumulated operation time of the main logic block 210 is greater than or equal to a threshold operation time, the control logic block 230 transmits a control signal for toggling to the switch 240 through the switching control logic 236. When the toggling from the main logic block 210 to the main logic block 220 is performed, the main logic block 220 is connected to the other logic 250 as a result of the toggling.

The control register 232 stores a table in which temperature and bit data is mapped. Temperature information measured by a temperature sensor with respect to the main logic block 210 is transferred to the control register 232. When a temperature of the main logic block 210 is greater than or equal to a threshold temperature, the control logic block 230 transmits the control signal for toggling to the switch 240 through the switching control logic 236. When toggling from the main logic block 210 to the main logic block 220 is performed, the main logic block 220 is connected to the other logic 250 as a result of the toggling.

The combinational logic 233 determines the toggling of the main logic block 210 based on a combination of the operation time information and the temperature information on the main logic block 210. For example, the control signal for the toggling of the main logic block 210 is generated when the accumulated operation time of the main logic block 210 is greater than the threshold operation time and when the temperature of the main logic block 210 is greater than the threshold temperature.

Although not shown in FIG. 2, the control logic block 230 may further include a register configured to record the performance of the main logic block 210. For example, the control logic block 230 may further include a register to record an error occurring in a bitstream generated by the main logic block 210. When a number of errors is greater than or equal to a threshold, the control logic block 230 determines that the toggling condition of the main logic block 210 is satisfied.

In response to the toggling to the main logic block 220, the control logic block 230 acquires the operation state information on the main logic block 220. The control logic block 230 verifies whether the toggling condition of the main logic block 220 is satisfied, based on the operation state information on the main logic block 220. When the toggling condition is satisfied, the toggling of the main logic block is performed and thus, the main logic block 210 is connected to the other logic 250.

The main logic blocks 210 and 220 may not be used concurrently. A clock/power gating may be applied to an unused main logic block, thereby preventing a power waste.

Repeated descriptions will be omitted for increased clarity and conciseness because the descriptions provided with reference to FIG. 1 are also applicable to FIG. 2.

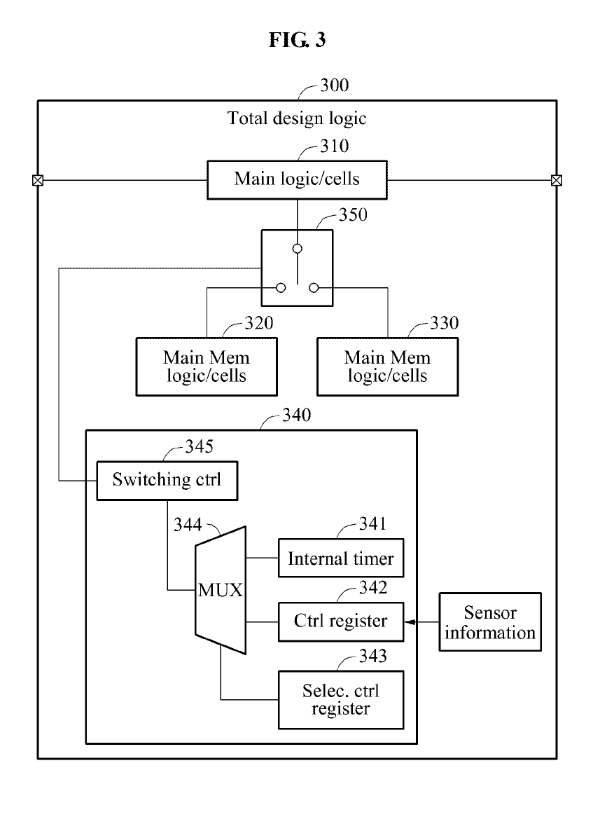

FIG. 3 is a diagram illustrating another example of a total design logic of a chip. Hereinafter, the total design logic 300 may also be referred to as the digital design logic 300. Referring to FIG. 3, the digital design logic 300 includes a main logic/cells 310, a plurality of memory units, for example, a main memory logic/cells 320 and a main memory logic/cells 330, a controller 340, and a switch 350. Hereinafter, the main logic/cells 310 may also be referred to as the logic unit 310. Also, the main memory logic/cells 320 and the main memory logic/cells 330 may also be referred to as the memory unit 320 and the memory unit 330, respectively.

The logic unit 310 may be a logic using a memory requisitely or frequently. The logic unit 310 accesses the memory units 320 and 330. In this example, the logic unit 310 does not access the memory units 320 and 330 concurrently. The logic unit 310 accesses a memory unit connected through the switch 350.

The controller 340 includes an internal timer 341, a control register 342, a selection control register 343, a MUX 344 and a switching control logic 345. When a first signal based on the temperature information and a second signal based on the operation time information are transferred to the MUX 344, a specific signal is selected among the first signal and the second signal based on a selection signal of the selection control register 343. The selection control register 343 may transfer the selection signal to MUX 344 which is used to select the specific signal. MUX 344 may transfer the specific signal to the switching control logic 345. The switching control logic 345 may generate the control signal for toggling, based on the specific signal.

The controller 340 acquires operation state information on a memory unit accessed by the logic unit 310 among the plurality of memory units. In this example, the logic unit 310 accesses the memory unit 320. The controller 340 acquires operation state information on the memory unit 320. The acquired operation state information corresponds to at least one of temperature information and operation time information.

The controller 340 acquires operation time information on the memory 320 using an internal timer 341. When an accumulated operation time of the memory unit 320 is greater than or equal to a threshold operation time, the controller 340 generates a control signal to toggle the memory unit 320. Based on the control signal, the switch 350 toggles the memory unit 320, and the logic unit 310 accesses the memory unit 330.

The controller 340 acquires temperature information on the memory unit 320. A temperature of the memory unit 320 is measured using a temperature sensor disposed internally or externally to the chip. The temperature information on the memory unit 320 is transferred to a control register 342. The control register 342 stores a table in which temperature and bit data is mapped. The controller 340 verifies whether the temperature of the memory unit 320 is greater than or equal to a threshold temperature based on the table. When the temperature of the memory 320 is greater than or equal to the threshold temperature, the controller 340 transfers the control signal through a switching control unit 345. The switch 350 toggles the memory unit 320 and, in response to the toggling, the logic unit 310 accesses the memory unit 330.

The plurality of memory units are toggled by determining whether a toggling condition is satisfied. As a result of the toggling, degradation in performances of the plurality of memory units and the chip is prevented.

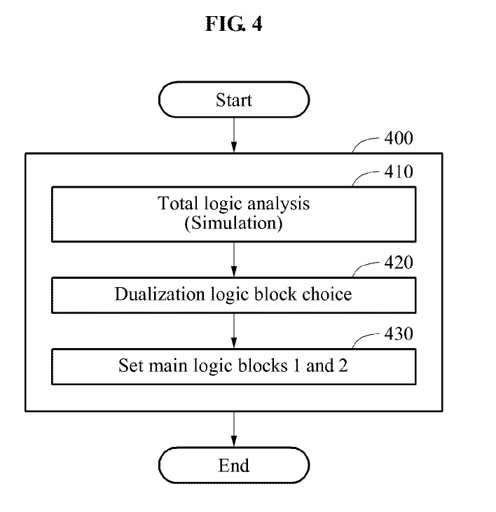

FIG. 4 is a flowchart illustrating the determination of a main logic unit described with reference to FIG. 1 and the determination of a main logic block described with reference to FIG. 2.

In operation 410, a total logic analysis is performed. For example, a simulation is applied to a digital logic design. In this example, the applied simulation is, for example, a post-layout simulation. Through the simulation, a logic block corresponding to a relatively high application frequency is predicted from among logic blocks included in the digital logic design. Also, through the simulation, a logic block corresponding to relatively high power consumption is predicted from among the logic blocks included in the digital logic design.

In operation 420, a dualization logic block choice is performed. For example, after the applying of the simulation, a main logic block to be dualized is selected from the digital logic design. The main logic block to be dualized is determined based on a result of the simulation.

In response to the selecting of the main logic block to be dualized, a main logic block equal to the selected main logic block is added in the digital logic design. Through a dualization of the main logic block, the digital logic design includes a plurality of main logic blocks, each being equivalent to one another.

In operation 430, main logic blocks 1 and 2 are set. For example, a main logic block to be used initially is set among the plurality of main logic blocks. In this example, the main logic block to be used initially is set as the main logic block 1 and, each of remaining main logic blocks is set as the main logic block 2. The main logic block corresponding to a relatively high application frequency or power consumption is determined in the digital logic design, and the main logic block is dualized.

Operations 410 through 430 of FIG. 4 are also referred to as a pre-process 400 for dualization. The chip 100 of FIG. 1 and the digital logic design 200 of FIG. 2 are provided as results obtained by applying the pre-process 400. In response to an application of the pre-process 400, the main logic unit of FIG. 1 and the main logic block of FIG. 2 are dualized, and the controller 130 and the control logic block 230 of FIG. 2 is added for the togging.

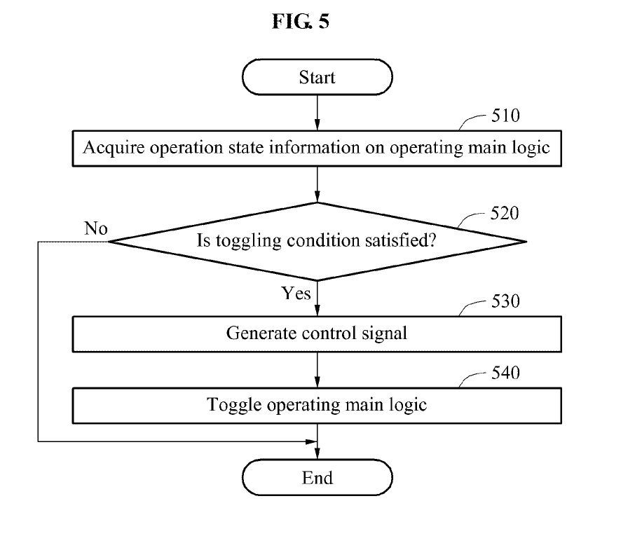

FIG. 5 is a flowchart illustrating an example of a chip control method.

Referring to FIG. 5, in operation 510, a chip acquires operation state information on a main logic operating in response to an enable signal among a plurality of main logics included in the chip. The chip includes the plurality of main logics, and the main logics do not operate concurrently. Using a switch, one of the plurality of main logics operates in response to an application of the enable signal.

Each of the plurality of main logics is equivalent. A main logic is determined from among a plurality of logics included in the chip based on a post-simulation result. For example, when the post-simulation is applied to an initial digital design, application frequencies or power consumption of the plurality of logics is verified. A logic corresponding to a highest application frequency or power consumption is determined as the main logic among the plurality of logic. The chip includes a plurality of main logics as a result of dualizing the main logic.

The operation state information includes at least one of temperature information, operation time information, and error information on the main logic.

In operation 520, the chip determines whether a toggling condition of the main logic is satisfied, based on the operation state information. In this example, the toggling condition is at least one of a first condition indicating whether an accumulated operation time of the main logic operating in response to the enable signal is greater than or equal to a threshold time, a second condition indicating whether a temperature of the main logic is greater than or equal to a threshold temperature, and a third condition indicating while the enable signal is being allied to the main logic, a number of errors occurring in the bitstream generated by the main logic in operating in response to the enable signal.

In operation 530, when the toggling condition is satisfied, the chip generates a control signal for toggling. In operation 540, the chip toggles the main logic operating in response to an application of the enable signal.

In response to the toggling, another main logic performs an identical operation to the operation of the main logic.

In an example of a chip operation method, a chip acquires operation state information on a memory unit accessed by a logic unit among a plurality of memory units. The chip determines whether a toggling condition of the memory unit is satisfied, based on operation state information. The chip generates a control signal for toggling based on a result of the determining The chip toggles the memory unit accessed by the logic unit based on the control signal. In this example, the chip includes a plurality of memory units, and at least one logic unit to access the plurality of memory units. The at least one logic unit does not access the plurality of memory units concurrently. The at least one logic unit accesses a memory unit connected through a switch.

Repeated descriptions will be omitted for increased clarity and conciseness because the descriptions provided with reference to FIGS. 1 through 4 are also applicable to FIG. 5.

Example embodiments prolong a life cycle of a chip, or a terminal and a system including the chip. In example embodiments, dualization is performed on a cell or a block logic predicted through layout simulation in lieu of using a compensation method through an external access, and the dualized cell or block logic is controlled based on a switching condition. Through the dualization, an increase in power consumption due to degradation is prevented.

Additionally, example embodiments may not use an external device for a compensation control.

The various units, modules, and structural elements, described above may be implemented using one or more hardware components, including, for example, processors, circuits and the like.

The methods described above can be written as a computer program, a piece of code, an instruction, or some combination thereof, for independently or collectively instructing or configuring the processing device to operate as desired. Software and data may be embodied permanently or temporarily in any type of machine, component, physical or virtual equipment, computer storage medium or device that is capable of providing instructions or data to or being interpreted by the processing device. The software also may be distributed over network coupled computer systems so that the software is stored and executed in a distributed fashion. In particular, the software and data may be stored by one or more non-transitory computer readable recording mediums. The non-transitory computer readable recording medium may include any data storage device that can store data that can be thereafter read by a computer system or processing device. Examples of the non-transitory computer readable recording medium include read-only memory (ROM), random-access memory (RAM), Compact Disc Read-only Memory (CD-ROMs), magnetic tapes, USBs, floppy disks, hard disks, optical recording media (e.g., CD-ROMs, or DVDs), and PC interfaces (e.g., PCI, PCI-express, Wi-Fi, etc.). In addition, functional programs, codes, and code segments for accomplishing the example disclosed herein can be construed by programmers skilled in the art based on the flow diagrams and block diagrams of the figures and their corresponding descriptions as provided herein.

While this disclosure includes specific examples, it will be apparent to one of ordinary skilled in the art that various changes in form and details may be made in these examples without departing from the spirit and scope of the claims and their equivalents. The examples described herein are to be considered in a descriptive sense only and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A chip comprising:
main logic units; and
a controller configured to acquire operation state information on a main logic unit operating in response to an enable signal, among the main logic units, determine whether a toggling condition of the main logic unit is satisfied based on the operation state information, and generate a control signal for toggling of the main logic unit based on a result of the determining. The chip of claim 1, further comprising:
a toggling unit configured to toggle the main logic unit operating in response to the enable signal, based on the control signal.

3. The chip of claim 1, wherein the operation state information comprises at least one of error information, operation time information, and temperature information on the main logic unit operating in response to the enable signal.

4. The chip of claim 1, wherein the controller comprises an internal timer configured to acquire an operation time of the main logic unit operating in response to the enable signal.

5. The chip of claim 1, wherein the controller comprises a control register configured to store a table in which temperature and bit data are mapped.

6. The chip of claim 1, wherein the controller is configured to monitor a performance of the main logic unit operating in response to the enable signal.

7. The chip of claim 1, wherein the toggling condition is one of a first condition indicating whether an accumulated operation time of the main logic unit operating in response to the enable signal is greater than or equal to a threshold time, a second condition indicating whether a temperature of the main logic unit is greater than or equal to a threshold temperature, and a third condition indicating whether, during a process of applying the enable signal to the main logic unit, a number of errors occurring in a bitstream generated by the main logic unit is greater than or equal to a threshold.

8. A chip comprising:
memory units;
a logic unit configured to access the memory units; and
a controller configured to acquire operation state information on a memory unit accessed by the logic unit among the memory units, determine whether a toggling condition of the memory unit is satisfied based on the operation state information, and generate a control signal for toggling of the memory unit based on a result of the determining.

9. The chip of claim 8, further comprising:
a toggling unit configured to toggle the memory accessed by the logic unit based on the control signal.

10. The chip of claim 8, wherein the operation state information comprises one of temperature information and operation time information on the memory unit accessed by the logic unit.

11. The chip of claim 8, wherein the toggling condition is one of a first condition indicating whether an accumulated operation time of the memory unit accessed by the logic unit is greater than or equal to a threshold time, and a second condition indicating whether a temperature of the memory unit is greater than or equal to a threshold temperature.

12. The chip of claim 8, wherein the controller comprises an internal timer configured to acquire an operation time of the memory unit accessed by the logic unit.

13. The chip of claim 8, wherein the controller comprises a control register configured to store a table in which temperature and bit data is mapped.

14. A chip control method comprising:
acquiring operation state information on a main logic operating in response to an enable signal, among main logics;
determining whether a toggling condition of the main logic is satisfied based on the operation state information; and
generating a control signal for toggling the main logic based on a result of the determining.

15. The method of claim 14, further comprising:
toggling the main logic operating in response to the enable signal, based on the control signal.

16. The method of claim 14, wherein the operation state information comprises one of error information, operation time information, and temperature information on the main logic operating in response to the enable signal.

17. The method of claim 14, wherein the toggling condition is one of a first condition indicating whether an operation time of the main logic operating in response to the enable signal is greater than or equal to a threshold time, a second condition indicating whether a temperature of the main logic is greater than or equal to a threshold temperature, and a third condition indicating whether, during a process of applying the enable signal to the main logic, a number of errors occurring in a bitstream generated by the main logic is greater than or equal to a threshold.

18. The chip of claim 1, wherein the controller comprises a combinational logic unit configured to determine a toggling of the main logic unit operating in response to the enable signal based on the operation state information on the main logic unit operating in response to the enable signal, and wherein each of the main logic units is equivalent.

19. The chip of claim 2, where the controller comprises a switching control unit configured to transmit a control signal to the toggling unit.

20. The chip of claim 5, wherein the controller further comprises a selection control register configured to select data stored in the table of the control register.
